(19) United States
(12) Patent Application Publication
(10) Pub. No.: US 2021/0020663 A1
(43) Pub. Date: Jan. 21, 2021

(54) PROTECTING AN INTEGRATED CIRCUIT FROM THE DRILLING OF A SOURCE AND/OR DRAIN CONTACT

(71) Applicant: STMicroelectronics SA, Montrouge (FR)

(72) Inventors: Philippe GALY, Le Touvet (FR); Thomas BEDECARRATS, Saint Martin d'Heres (FR)

(73) Assignee: STMicroelectronics SA, Montrouge (FR)

(21) Appl. No.: 16/926,128

(22) Filed: Jul. 10, 2020

(30) Foreign Application Priority Data
Jul. 15, 2019 (FR) 1907925

(51) Int. Cl. H01L 27/12

(52) U.S. Cl. CPC H01L 27/1207

(57) ABSTRACT

An integrated circuit includes a MOS transistor that is located in and on a semiconductor film of a silicon-on-insulator (SOI) substrate. The SOI substrate has, below a buried insulator layer, a first back gate region and two first auxiliary regions that are located, respectively, below source and drain contact regions of the MOS transistor. The conductivity type of the two first auxiliary regions is the opposite the conductivity type of the first back gate region. The conductivity type of the two first auxiliary regions is identical to the conductivity type of the source and drain contact regions of the MOS transistor.

### PRIORITY CLAIM

This application claims the priority benefit of French Application for Patent No. 1907925, filed on Jul. 15, 2019, the content of which is hereby incorporated by reference in its entirety to the maximum extent allowable by law.

### TECHNICAL FIELD

Embodiments relate to integrated circuits and, in particular, to integrated circuits produced on a silicon-on-insulator substrate, for example a fully depleted silicon-on-insulator substrate (FDSOI). Embodiments more particularly relate to the protection of such integrated circuits from operations of drilling source and/or drain contacts that are then likely to come into contact with the back gate regions of MOS transistors.

### BACKGROUND

In FIG. 1, the reference ICI denotes an integrated circuit of conventional structure including a silicon-on-insulator (SOI) substrate, more particularly a fully depleted silicon-on-insulator substrate (FDSOI).

Such a substrate conventionally includes a semiconductor film FLM that is located above a buried insulator layer BOX, which is itself located above a carrier substrate including, in this example, a first semiconductor well 1 exhibiting p-type conductivity and a second semiconductor well 2 exhibiting n-type conductivity, these two semiconductor wells 1, 2 being electrically insulated from one another by a trench isolation, here a shallow trench isolation STI.

An NMOS transistor TRN is located in and on the portion of the semiconductor film FLM on the left in FIG. 1, while a PMOS transistor TRP is located in and on the right-hand portion of the semiconductor film FLM.

More specifically, the transistor TRN includes, within the semiconductor film FLM, n⁺-doped source SN and drain DN regions and an insulated front gate region GN.

The transistor TRP also includes a source region SP, a drain region DP and an insulated front gate region GP. The source and drain regions of the transistor TRP are p⁺-doped.

The portion 10 of the semiconductor well 1 that is located below the transistor TRN includes, in its upper portion, a p⁺-overdoped region forming a back gate BGN for this transistor TRN.

This back gate BGN can be biased (polarized) via contact with a p⁺-overdoped region in a portion 11 of the first semiconductor well 1.

The portion 20 of the second semiconductor well 2 includes an upper n⁺-overdoped region that is located below the buried insulator layer BOX and forms a back gate BGP for the transistor TRP.

This back gate BGP can be biased (polarized) through contact with an n⁺-overdoped region in a portion 21 of the second well 2.

The vertical arrows represent the various contacts made with the corresponding contact regions, for example the contact regions SN, DN, SP, DP corresponding to the source and drain regions of the transistors TRN and TRP, that allow the corresponding semiconductor regions to be biased, as well as the contact regions BGN and BGP for the back gates of the transistors.

These contacts are conventionally electrically conductive pads, for example made of tungsten, connecting the corresponding semiconductor regions to metal tracks of the first metallization level of the integrated circuit.

The various contacts are conventionally coated with a dielectric material, commonly referred to by those skilled in the art as PMD (pre-metal dielectric) layer (not shown).

However, as illustrated schematically in FIG. 2, it is possible, in the process of fabricating the integrated circuit and in particular when producing these contact regions SN, DN, SP, DP, for at least one of these contacts to pierce not only the corresponding semiconductor region that is intended to be biased by this contact, but also the subjacent portion of the buried insulator layer BOX, to come into contact with the back gate of the corresponding transistor.

Such a drilling operation, for example of drilling the drain region DN, is shown in FIG. 2.

The contact CT has then pierced this drain region DN and the subjacent portion of the buried insulator layer BOX to come into contact with the back gate BGN of the transistor TRN.

There is then a short circuit between the drain of the transistor TRN and its back gate, which obviously negatively affects the operation of the transistor TRN.

This drilling risk increases with decreasing the thickness of the semiconductor film FLM, and is particularly high in the case of FDSOI technologies in which the thickness of the semiconductor film is of the order of a few nanometers.

There is therefore a need to provide a solution to this problem.

### SUMMARY

According to one aspect, what is proposed is an integrated circuit including at least one MOS transistor that is located in and on a semiconductor film of a silicon-on-insulator substrate, for example a fully depleted silicon-on-insulator substrate, having, below a buried insulator layer, a first back gate region and two first auxiliary regions that are located, respectively, below source and drain contact regions of the NMOS transistor, and the conductivity type of which is the opposite of that of the first back gate region and identical to that of the source and drain contact regions of the NMOS transistor.

As such, even if a contact pierces, for example, the drain region or the source region of the transistor and reaches the region located below the buried insulating layer, this contact will touch the corresponding semiconductor auxiliary region exhibiting the same conductivity type as the source or drain region rather than the buried gate region, which exhibits the opposite conductivity type.

In this case, the effect of biasing the contact will be to bias the PN junction formed by the auxiliary region and the buried gate (or back gate) region. As the sources and drains of the NMOS (or PMOS) transistors are positively (or negatively) biased with respect to their back gates, the PN junctions are systematically reverse-biased.

There will therefore be no short circuit between the source or the drain and the back gate region; only the flow of a very small leakage current.

According to one embodiment, the integrated circuit includes, in and on the semiconductor film, at least one PMOS transistor, which is electrically insulated from the NMOS transistor and has, below the buried insulator layer, a second back gate region and two second auxiliary regions, which are electrically insulated from the first back gate region, the two second auxiliary regions being located, respectively, below source and drain contact regions of the PMOS transistor, and the conductivity type of which is the opposite of that of the second back gate region and identical to that of the source and drain contact regions of the PMOS transistor.

According to one embodiment, the semiconductor film located above the buried insulating layer has a first portion in and on which the NMOS transistor is located and a second portion, which is electrically insulated from the first portion, in and on which the PMOS transistor is located, the silicon-on-insulator substrate including:
a first semiconductor well including the first back gate region, the conductivity type of which is the opposite of that of the source and drain regions of the NMOS transistor and the two first auxiliary regions that are located on either side of the first back gate region; and
a second semiconductor well including the second back gate region, which is electrically insulated from the first back gate region, the conductivity type of which is the opposite of that of the source and drain regions of the PMOS transistor and the two second auxiliary regions that are located on either side of the second back gate region.

According to one embodiment: the source and drain contact regions of the NMOS transistor exhibit n-type conductivity; the first well and the first back gate region exhibit p-type conductivity; the source and drain contact regions of the PMOS transistor exhibit p-type conductivity; and the second well and the second back gate region exhibit n-type conductivity.

### BRIEF DESCRIPTION OF THE DRAWINGS

Other advantages and features of the invention will become apparent upon examining the detailed description of completely non-limiting embodiments and the appended drawings, in which:

FIG. 1 shows an integrated circuit of conventional structure including a silicon-on-insulator (SOI) substrate;

FIG. 2 shows a drilling of a source/drain contact piercing an underlying buried oxide of the SOI substrate to reach a back gate region;

FIG. 3 shows an integrated circuit including an SOI substrate and a structure for protecting against short circuit when drilling a source/drain contact; and

FIG. 4 shows the drilling of the source/drain contact piercing the underlying buried oxide of the SOI substrate without reaching the back gate region due to the structure for protecting.

### DETAILED DESCRIPTION

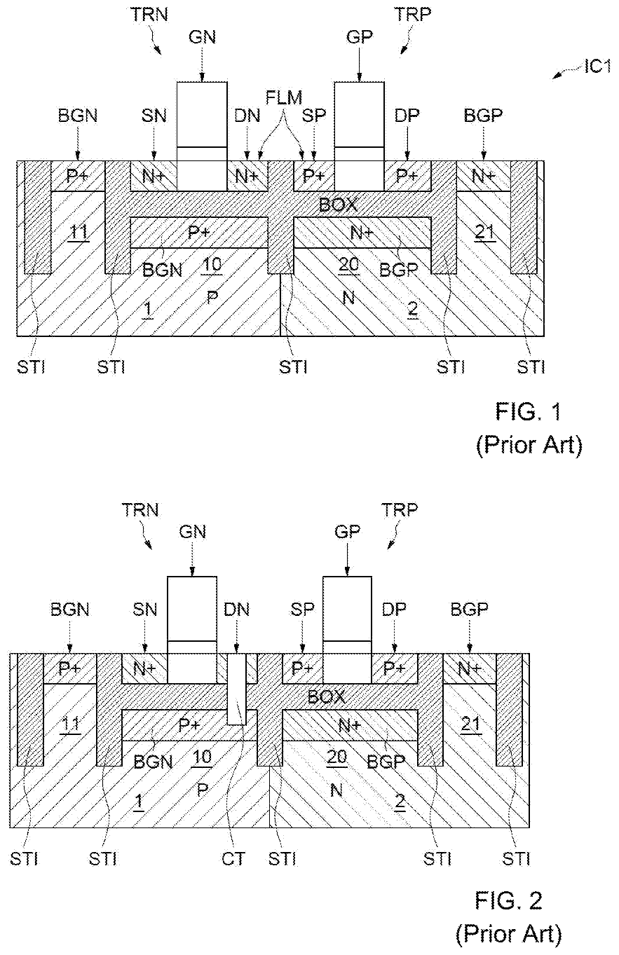

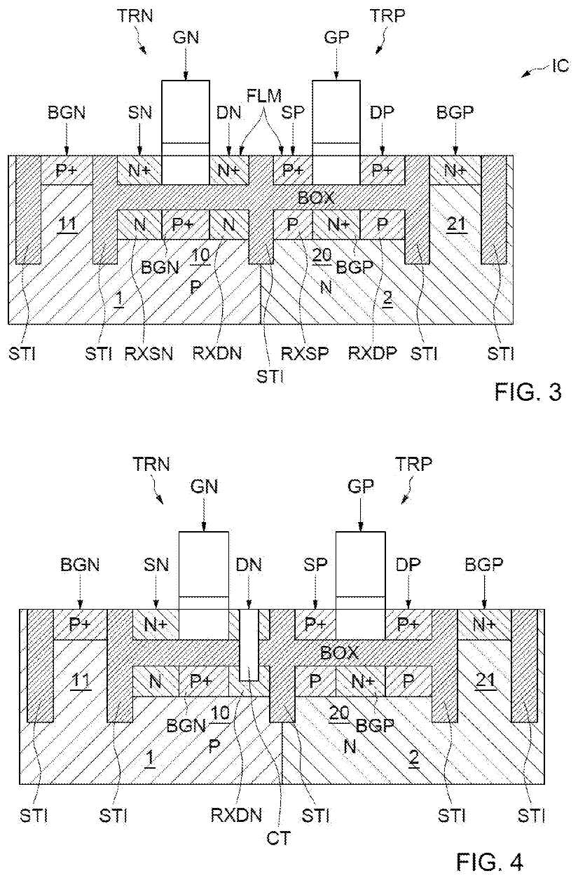

FIGS. 3 and 4 are views corresponding to the views of FIGS. 1 and 2, respectively.

What is illustrated is an integrated circuit IC including an NMOS transistor TRN and a PMOS transistor TRP that is located in and on a semiconductor film FLM of a silicon-on-insulator substrate, especially a fully depleted silicon-on-insulator (FDSOI) substrate.

This semiconductor film FLM is located above a buried insulator layer BOX.

The source SN and drain DN regions of the transistor TRN exhibit n⁺-type conductivity while the source SP and drain DP regions of the transistor TRP exhibit p⁺-type conductivity.

Furthermore, for the sake of simplicity, the references SN and DN, SP and DP also denote the contact regions for these source and drain regions.

It is with these contact regions that the contacts, represented by the vertical arrows and intended to bias these regions, will make contact.

The two transistors TRN and TRP are electrically insulated from one another by isolation regions STI.

The transistor TRN includes a p⁺-doped back gate BGN, located below the buried insulating layer BOX in the upper zone of the portion 10 of a first semiconductor well 1, which is located below the transistor TRN.

This back gate BGN can be biased (polarized) via the portion 11 of the first semiconductor well and p⁺-doped contact region at the upper surface of the substrate.

Similarly, the transistor TRP has an n⁺-doped back gate region BGP, also located in the upper zone of the portion 20 of a second semiconductor well, which is located below the transistor TRP, and can be biased (polarized) via the portion 21 of this second semiconductor well and n⁺-doped contact region at the upper surface of the substrate.

Conversely, unlike the prior art FIGS. 1-2, the integrated circuit of FIGS. 3-4 has two first auxiliary regions RXSN and RXDN that are located on either side of the back gate region BGN of the transistor TRN, and the conductivity type of which is identical to that of the contact regions SN and DN, namely n-type conductivity here.

As such, the conductivity type of these auxiliary regions RXSN and RXDN is the opposite of that of the back gate BGN.

These two first auxiliary regions RXSN and RXDN are located, respectively, below the source and drain contact regions SN and DN of the transistor TRN such that, in the event of the contact being drilled into one or both of the regions SN and DN, it will come into contact with one or both of the corresponding regions RXSN and RXDN.

The auxiliary region RXSN is insulated from the portion 11 of the first semiconductor well 1 by a part of the STI which extends through the film FLM, the BOX and partially into the well 1 below the BOX to a depth which is below a bottom of the auxiliary region RXSN.

Similarly, the integrated circuit IC includes two second auxiliary regions RXSP and RXDP that are located on either side of the back gate BGP of the transistor TRP, and below the source and drain contact regions SP and DP, respectively.

The conductivity type of these second auxiliary regions RXSP and RXDP is identical to that of the source and drain contact regions SP and DP, namely p-type conductivity here, this conductivity type therefore being the opposite of that of the back gate region BGP.

The auxiliary region RXDP is insulated from the portion 21 of the second semiconductor well 2 by a part of the STI which extends through the film FLM, the BOX and partially into the well 2 below the BOX to a depth which is below a bottom of the auxiliary region RXDP.

The STI surrounds the region 10 within which the first auxiliary regions RXSN and RXDN and back gate region BGN are located.

The STI surrounds the region 20 within which the second auxiliary regions RXSP and RXDP and back gate region BGP are located.

The auxiliary region RXDN is insulated from the auxiliary region RXSP by a part of the STI which extends into the wells 1, 2 below the BOX.

Thus, as illustrated schematically in FIG. 4, in the event of a contact CT, such as for example one that is intended to bias the drain region DN of the transistor TRN, being drilled, this contact passes through the drain contact region DN and the subjacent corresponding portion of the buried insulating layer BOX to come into contact with the corresponding first auxiliary region RXDN.

Consequently, there is no short circuit between the drain region DN and the back gate BGN of the transistor TRN.

1. An integrated circuit, comprising:
a first MOS transistor that is located in and on a semiconductor film of a silicon-on-insulator (SOI) substrate having, below a buried insulator layer, a first back gate region and two first auxiliary regions;
wherein the two first auxiliary regions are located, respectively, below source and drain contact regions of the first MOS transistor and on opposite sides of the first back gate region; and
wherein a conductivity type of the two first auxiliary regions is opposite a conductivity type of the first back gate region; and
wherein the conductivity type of the two first auxiliary regions is identical to a conductivity type of the source and drain contact regions of the first MOS transistor; and
wherein the first back gate region is coupled to a first back gate biasing contact region having a conductivity type opposite the conductivity type of the two first auxiliary regions.

2. The integrated circuit according to claim 1, wherein the first MOS transistor is an NMOS transistor.

3. The integrated circuit according to claim 1, wherein the first MOS transistor is a PMOS transistor.

4. The integrated circuit according to claim 1, further comprising a shallow trench isolation structure which extends through the semiconductor film, through the buried insulator layer and partially into a semiconductor well under the buried insulator layer, wherein the semiconductor well includes the two first auxiliary regions and the first back gate region and couples the first back gate region to the first back gate biasing contact region, and wherein the shallow trench isolation structure is in contact with the two first auxiliary regions.

5. The integrated circuit according to claim 4, wherein the shallow trench isolation structure surrounds a region of the semiconductor well which includes the two first auxiliary regions and the first back gate region.

6. The integrated circuit according to claim 5, wherein the shallow trench isolation structure has a depth which extends below a bottom of the two first auxiliary regions.

7. The integrated circuit according to claim 1, further including, in and on the semiconductor film, a second MOS transistor, which is electrically insulated from the first MOS transistor and further wherein the first and second MOS transistors are of opposite conductivity type, said second MOS transistor having, below the buried insulator layer, a second back gate region and two second auxiliary regions;
wherein the two second auxiliary regions are located, respectively, below source and drain contact regions of the second MOS transistor; and
wherein a conductivity type of the two second auxiliary regions is opposite a conductivity type of the second back gate region; and
wherein the conductivity type of the two second auxiliary regions is identical to the conductivity type of the source and drain contact regions of the second MOS transistor; and
wherein the second back gate region is coupled to a second back gate biasing contact region having a conductivity type opposite the conductivity type of the two second auxiliary regions.

8. The integrated circuit according to claim 7, wherein the first back gate region is electrically insulated from the second back gate region.

9. The integrated circuit according to claim 7, wherein the semiconductor film located above the buried insulating layer has a first portion in and on which the first MOS transistor is located and a second portion, which is electrically insulated from the first portion, in and on which the second MOS transistor is located.

10. The integrated circuit according to claim 9, wherein the silicon-on-insulator substrate includes:
a first semiconductor well including the first back gate region, the conductivity type of which is the opposite of that of the source and drain regions of the first MOS transistor and the two first auxiliary regions that are located on either side of the first back gate region, wherein the first semiconductor well couples the first back gate region to the first back gate biasing contact region; and
a second semiconductor well including the second back gate region, which is electrically insulated from the first back gate region, the conductivity type of which is the opposite of that of the source and drain regions of the second MOS transistor and the two second auxiliary regions that are located on either side of the second back gate region, wherein the second semiconductor well couples the second back gate region to the second back gate biasing contact region.

11. The integrated circuit according to claim 10, wherein the source and drain contact regions of the first MOS transistor exhibit n-type conductivity, and the first well and the first back gate region exhibit p-type conductivity, and wherein the source and drain contact regions of the second MOS transistor exhibit p-type conductivity, and the second well and the second back gate region exhibit n-type conductivity.

12. The integrated circuit according to claim 7, further comprising a shallow trench isolation structure which extends through the semiconductor film, through the buried insulator layer and partially into a semiconductor well under the buried insulator layer, wherein the semiconductor well includes the two second auxiliary regions and the second back gate region and couples the second back gate region to the second back gate biasing contact region, and wherein the shallow trench isolation structure is in contact with the two second auxiliary regions.

13. The integrated circuit according to claim 12, wherein the shallow trench isolation structure surrounds a region of the semiconductor well which includes the two second auxiliary regions and the second back gate region.

14. The integrated circuit according to claim 13, wherein the shallow trench isolation structure has a depth which extends below a bottom of the two second auxiliary regions.

15. The integrated circuit according to claim 1, wherein the SOI substrate is a fully depleted silicon-on-insulator substrate.
